(19) United States
(12) Patent Application Publication
(10) Pub. No.: US 2007/0246717 A1
(43) Pub. Date: Oct. 25, 2007

(54) Light source having both thermal and space efficiency

(76) Inventor: Kee Yean Ng, Prai (MY)

Correspondence Address: Kathy Manke;Avago Technologies Limited, 4380 Ziegler Road, Fort Collins, CO, 80525, US

(21) Appl. No.: 11/409,391

(22) Filed: Apr. 21, 2006

(51) Int. Cl. H01L 33/00

(52) U.S. Cl. 257/81

(57) ABSTRACT

A light source that is both thermally and spatially efficient can be achieved by attaching a light source, such as an LED chip, to a flexible circuit and positioning a light conductive material around the light source. For one embodiment, a cavity is created around the light source such that the light conductive material, for example, clear silicone, can be positioned within the cavity. In one embodiment, the cavity is created by a housing, such as a premolded plastic housing, secured to the flexible circuit. In one embodiment, a lens can be secured to the device to form the light.

### TECHNICAL FIELD

This invention relates to light sources and more specifically to light sources that are both thermally and space efficient.

### BACKGROUND OF THE INVENTION

Prior art light sources, such as light emitting diode (LED) light sources, typically have an LED chip attached to a printed circuit board (PCB). A wire connection is made between the LED chip and the PCB substrate. The assembly is then encapsulated with a light transparent material, such as clear epoxy. This arrangement suffers from two disadvantages, namely, the package is thick (on the order of 0.25 to 1.0 mm and has relatively low heat dissipation from the LED through the PCB.

Prior attempts to correct the thermal transfer problems have been to increase the thickness of the plating that is used to electronically connect the LCD chip. However there is a limit as to how much the plating can be increased. The thickness (space) issue has been addressed by reducing the thickness of the substrate. Here again, there is a limit as to how thin the PCB can be made. Usually it is not practical to reduce the PCB to less than 0.15 mm in thickness.

### BRIEF SUMMARY OF THE INVENTION

A light source that is both thermally and spatially efficient can be achieved by attaching a light source, such as an LED chip, to a flexible circuit and positioning a light conductive material around the light source. For one embodiment, a cavity is created around the light source such that the light conductive material, for example, clear silicone, can be positioned within the cavity. In one embodiment, the cavity is created by a housing, such as a premolded plastic housing, secured to the flexible circuit. In one embodiment, a lens can be secured to the device to form the light.

### BRIEF DESCRIPTION OF THE DRAWINGS

FIG. 1 shows one embodiment of a light source mounted on a flexible circuit;

FIG. 2 shows an embodiment of the device of FIG. 1 having a lens attached thereto;

FIG. 3 shows one embodiment of a method of constructing the light source; and

FIG. 4 shows one embodiment of a light source mounted on a flexible circuit without a housing.

### DETAILED DESCRIPTION OF THE INVENTION

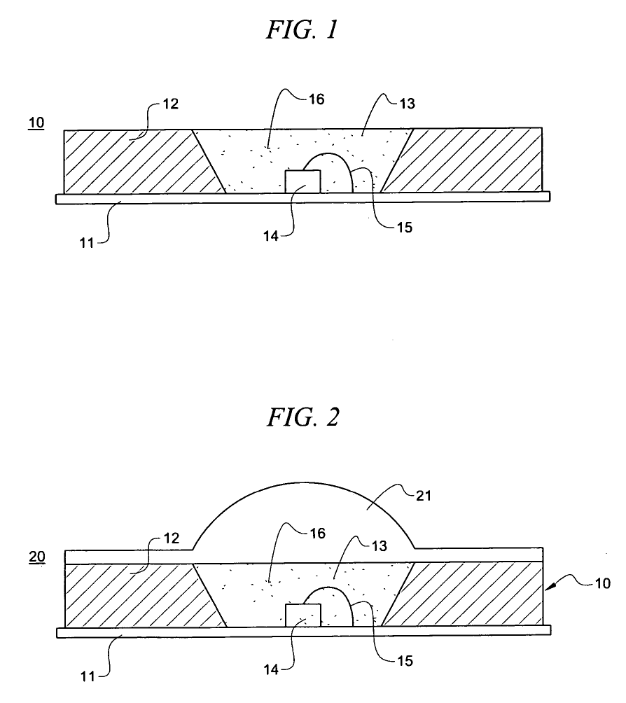

FIG. 1 shows one embodiment of light source 10 mounted on flexible circuit 11 as a substrate. An LED chip is attached to flexible circuit 11 and a wire bond 15 is made between LED chip 14 and circuit 11. Flexible circuit 11 can be, for example, fabricated of a polymer material, such as polyamide. Housing 12 having cavity 13 is positioned over the flexible circuit and attached thereto. Encapsulant 16, which preferably can be clear epoxy, is then inserted within cavity 13.

Housing 12 could be, for example, molded using plastic or any other desired material. Encapsulant 16 could fill cavity 13 forming a top surface that is plumb with the top surface of housing 12 or the encapsulant could, for example, fill less than the entire cavity and be formed, if desired, into a lens. The encapsulant protects the light source from the external environment. In some situations, the encapsulant material can be used to support the light source and/or to form a pocket to house a lens.

The flexible circuit can be made relatively thin, for example, having 0.1 mm of thickness or less. Since the flexible circuit is thin (providing space efficiency), heat is more easily conducted through the flexible circuit and away from LED chip 14, thereby providing increased thermal efficiency.

FIG. 2 shows one embodiment 20 in which a lens, such as lens 21, is positioned with respect to cavity 13. If desired, lens 21 could be above cavity 13 as shown or could be within (or partially within) the cavity. The lens could be a separate structure (as shown) or could be formed as part of the light conductive support material (encapsulant). The lens accepts light from the light source and concentrates or focuses the light (or changes the color of the light) as desired.

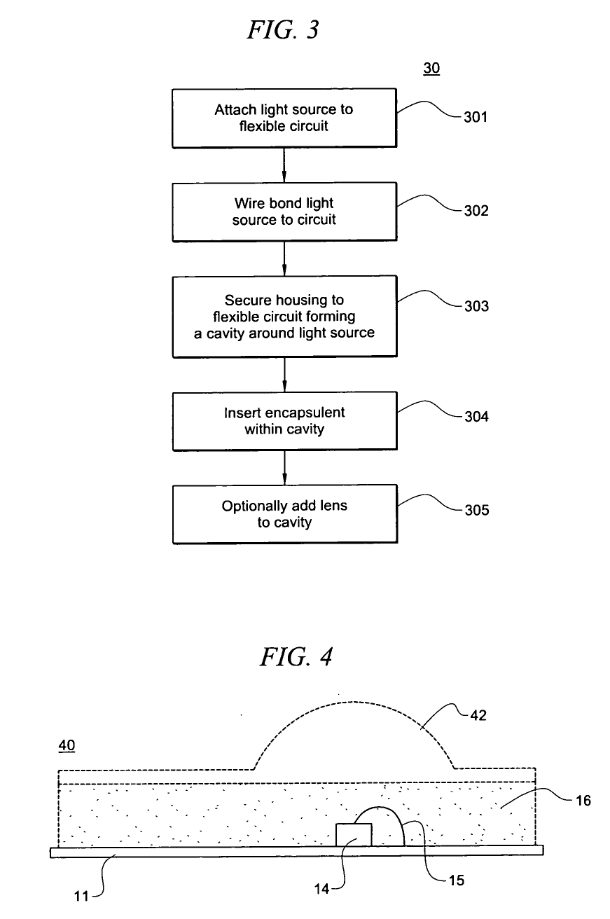

FIG. 3 shows one embodiment 30 of a method for manufacturing light sources having both thermal and spatial efficiency. In process 301 the light source such as an LED, is attached to the flexible circuit using, for example, silver epoxy or any other die attachment method. In process 302 the wire from the top of the LED is attached to the flexible circuit, for example, by soldering or any other attachment method.

In process 303, the housing is then attached (by gluing or otherwise) to the flexible circuit. The housing either has cavity 13 (FIG. 1) preconstructed therein or forms a cavity when attached to the flexible circuit. In process 304, encapsulant, such as silicone, is dispensed into the cavity and cured. The encapsulant can be any light conductive material that can serve to protect and maintain the light source in position within the cavity, and if desired, provide structural support for the light source.

In process 305, optional lens can be placed on the top of (or within or partially within) the cavity. Note that the lens can be added after the encapsulant support material is in position, or the lens can be integral with the housing. If the lens is added integral to the housing, the uncured silicone could be inserted through the housing (perhaps through a sealable hole) after the housing is mated to the substrate. Also, the encapsulant can be premolded into the housing in some situations.

FIG. 4 shows one embodiment of a light source 40 in which encapsulant 16 is positioned around LED 14 and in contact with flexible circuit 11. In this embodiment, there is no housing. Note that lens 42 is optional as depicted.

Encapsulant 16 (in this embodiment as well as in the other embodiments shown) can be loaded with a color shifting material, for example, phosphor, such that colored light different from that emitted by the LED can be obtained. For example, white light can be obtained by combining a blue LED and yellow phosphor materials.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A light device comprising:
a flexible circuit substrate;
a light source mounted on, and electrically connected to, said flexible circuit; and
light conductive encapsulant material positioned around said light source.

2. The light device of claim 1 further comprising:
a housing mounted to said flexible circuit, said housing forming a cavity around said mounted light source, and wherein said light conductive material is within said cavity.

3. The light device of claim 1 wherein said light source is an LED chip.

4. The light device of claim 2 wherein said flexible circuit has a thickness less than or equal to 0.1 mm.

5. The light device of claim 1 further comprising:
a lens positioned with respect to said housing to accept light from said light source.

6. The light device of claim 5 wherein said lens is formed as part of said encapsulant.

7. The method of manufacturing an LED, said method comprising:
mounting an LED chip mechanically and electronically to a flexible circuit;
creating a cavity around a mounted LED chip; and
at least partially filling said cavity with a light conductive encapsulant.

8. The method of claim 7 wherein said encapsulant is flexible.

9. The method of claim 7 wherein said encapsulant is silicone and wherein said silicone is inserted within said cavity in uncured form and allowed to cure within said cavity.

10. The method of claim 9 wherein said cavity is formed by a premolded housing surrounding said LED chip and attached to said flexible circuit.

11. The method of claim 10 wherein said housing is plastic.

12. The method of claim 10 wherein said housing has a lens integral therewith.

13. A light device comprising:
a flexible circuit substrate;
a light source mounted on said flexible substrate; and
light source supporting material on said substrate, said material surrounding said light source and operative for conducting light from said light source to a top surface of said supporting material.

14. The light device of claim 13 wherein a cavity is formed on said substrate and wherein said light source and said supporting material are within said formed cavity.

15. The light device of claim 14 wherein said material fills said cavity.

16. The light device of claim 14 wherein said cavity is formed, at least in part, by a rigid housing mated to said substrate.

17. The light device of claim 15 wherein said housing is at least partially plastic.

18. The light device of claim 13 further comprising:
a lens for communicating light from said light source to a location outside of said supporting material, said lens in a fixed relationship with said top of said supporting material.

19. The light device of claim 14 further comprising:
a housing mated with said substrate, said housing forming said cavity, and a lens is positioned on a top surface of said housing.

20. The light device of claim 19 wherein said lens and said housing form an integral structure.
